(19) United States
(12) Patent Application Publication
(10) Pub. No.: US 2006/0120199 A1
(43) Pub. Date: Jun. 8, 2006

(54) Electronic circuit

(76) Inventors: Carsten Ohlhoff, Dresden (DE); Hans-Christoph Ostendorf, Neubiberg (DE); Stefan Gollmer, Munchen (DE)

Correspondence Address: JENKINS, WILSON & TAYLOR, P. A., 3100 TOWER BLVD, SUITE 1200, DURHAM, NC, 27707, US

(21) Appl. No.: 11/270,025

(22) Filed: Nov. 9, 2005

(30) Foreign Application Priority Data
Nov. 12, 2004 (DE) 102004054874.9

(51) Int. Cl. G11C 5/14

(52) U.S. Cl. 365/229

(57) ABSTRACT

An electronic circuit comprises a volatile memory unit and a non-volatile memory unit which stores a repair information related to the volatile memory unit. The non-volatile and volatile memory units are connected together by a connecting device and are formed as a single electronic module.

### BACKGROUND OF THE INVENTION

1. Field of the Invention

The present invention relates generally to electronic circuit arrangements with different circuit units, and relates in particular to circuit arrangements which have volatile and non-volatile memory units and which are formed in so-called multi-chip arrangements.

2. Description of the Related Art

In the fabrication of large scale integrated circuit units, such as, for example, memory chips (e.g. DRAM, Dynamic Random Access Memory), the problem arises that they cannot be fabricated in a manner free of defects with sufficient yield. In order to solve this problem, a region of redundant memory cells is provided in conventional fabrication methods for memory chips of this type.

In the context of fabricating the memory chips on a wafer, a plurality of functional tests are carried out in which memory cells which are defective or “marginal” (situated in a critical operating state) are identified. In the conventional method, for this purpose an external test system is connected to a circuit arrangement to be verified, addresses of defective memory cells being determined. A repair solution is calculated on the basis of these data, which involves defining which defective cell is to be repaired with which redundant line. In accordance with the method according to the prior art, the repair information determined in this case has to be stored individually, that is to say in “non-volatile fashion” on the memory module in order to preserve the information in a memory cell array at any time and in order that, each time the entire circuit arrangement is started up anew (power up), those accesses which are directed to addresses identified as defective can be diverted to functional redundant memory elements.

Consequently, the problem arises of storing repair information of this type in the circuit arrangement. An item of repair information of this type is usually impressed or stored in the circuit arrangement by means of so-called laser fuses. These are essentially metal or polysilicon webs which can be severed with the aid of high-energy laser radiation in production in order thus to represent in each case a logic “0” or a logic “1”.

It is disadvantageous that such storage of repair information can be performed only when the memory module is freely accessible, that is to say when the entire circuit arrangement is not yet situated in a housing. Once the circuit arrangement has been incorporated into the housing, the so-called laser fuses are inexpediently no longer accessible.

This results in the significant disadvantage that all defects found by the test system after the entire circuit arrangement has been packaged in the housing, for example in functional tests, cannot be repaired.

In order to solve this problem, the prior art has proposed the use of so-called electrical fuses or antifuses. These are non-volatile memory elements which can be programmed by applying a high voltage or conducting a high current through them.

A significant disadvantage of such electrical fuses, however, is that they require a high space requirement on the electronic circuit arrangement. This involves components such as a generator for generating high voltages, an addressing logic for the fuses, etc.

Furthermore, it is inexpedient that the fabrication process for the entire circuit arrangement, in particular for the volatile memory present in the circuit arrangement, becomes more complex and thus more expensive as a result of electrical fuses of this type. This has the effect, therefore, that additional processing steps are required for providing the electronic fuses (e-fuses). Since the volatile memories (in particular DRAM) present in the circuit arrangement are a mass-produced product, it is extremely disadvantageous to increase the fabrication costs by the provision of additional electronic fuses.

### SUMMARY OF THE INVENTION

It is an object of the present invention to provide a circuit arrangement in which volatile memory units identified as defective can be repaired after introduction to a housing, without increasing the space requirement and the costs of the entire circuit arrangement.

The object is achieved in accordance with the invention by means of a electronic circuit arrangement comprising:

a) a volatile memory unit;

b) a non-volatile memory unit; and

c) a connecting device for connecting the volatile memory unit to the non-volatile memory unit, the volatile memory unit and the non-volatile memory unit being formed as a single circuit chip, an item of repair information relating to the volatile memory unit being stored in the non-volatile memory unit.

One essential concept of the invention consists in forming a volatile memory unit of the circuit arrangement and a non-volatile memory unit as a single circuit chip or a single electronic module, an item of repair information relating to the volatile memory unit being stored in the non-volatile memory unit.

The required storage of the repair information essentially consists of the addresses of the defective memory elements, an item of repair information of this type now being stored externally, on a separate (non-volatile) memory chip, rather than on the volatile memory component (e.g. the DRAM) itself. In an advantageous manner, semiconductor memories are increasingly being provided as so-called multi-chip packages (MCP) in which at least two dies (circuit chips) are accommodated in a common package (housing). The combination of non-volatile memory units such as, for example, flash memory units with the customary volatile memory units (e.g. SRAM or pseudo-SRAM) is very simple and widespread in this case.

This affords the advantage that the combination of a plurality of circuit units in a common housing leads to a small structural size and thus to a low space requirement.

Furthermore, this affords the advantage that a respective volatile memory unit is fixedly and unambiguously connected to a corresponding non-volatile memory unit, so that the latter may potentially also be used for storing items of information accessed by the volatile memory unit.

The volatile memory unit may be a dynamic random access memory.

It may be advantageous to form the connecting device as an electrical connection of the volatile memory unit to the non-volatile memory unit in the form of electrical connections e.g. in the form of binding wires.

In a restricted version of the inventive device the connecting device is provided as a device which provides a radio connection of the volatile memory unit to the non-volatile memory unit. The connecting device is preferably formed by radiofrequency transceivers.

The connecting device may provide an optical connection of the volatile memory unit to the non-volatile memory unit by means of optical transceivers.

A non-volatile memory unit with at least two volatile memory units may be accomodated in a single circuit chip (housing). In this way, the electronic circuit arrangement provides the possibility of permanently eliminating defects in a volatile memory unit after the latter has been packaged in a housing, without increasing the overall space requirement and the fabrication costs of the entire circuit arrangement.

### DESCRIPTION OF THE DRAWINGS

FIG. 1 is an overall block diagram of a first exemplary embodiment of an inventive circuit arrangement in which a volatile memory unit and a non-volatile memory unit are accommodated in a common housing;

FIG. 2 is a flow diagram for elucidating a test sequence between the volatile memory unit and the non-volatile memory unit directly via a signal line;

FIG. 3 is a schematic flow diagram for illustrating an initialization procedure of a multi-chip circuit arrangement according to the invention in accordance with a further preferred exemplary embodiment of the present invention; and

FIG. 4 is a further exemplary embodiment, illustrating an exchange of information between the non-volatile memory unit and the volatile memory unit via a memory controller.

In the Figures, identical reference symbols designate identical or functionally identical components or steps.

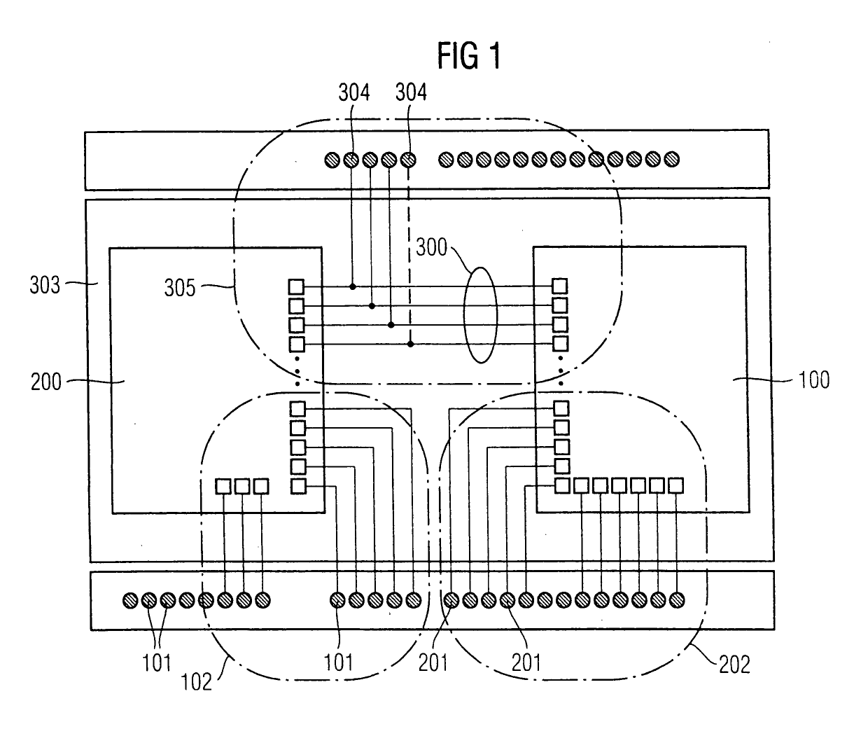

FIG. 1 illustrates a block diagram of an electronic circuit arrangement in accordance with one preferred exemplary embodiment of the present invention. Both a volatile memory unit 100 and a non-volatile memory unit 200 are accommodated in a common housing 303. Although the present invention is not restricted thereto, a connecting device 300 is shown, which comprises electrical conductor tracks and provides an electrical connection between the volatile memory unit 100 and the non-volatile memory unit 200.

In this case, a common connection region 305 serves both for connecting the volatile memory unit 100 to the non-volatile memory unit 200 and for a possibility of external connection to external circuit units (not shown) by common connection units 304.

A possibility of connection to external circuit units is not absolutely necessary. If such a functionality is not required, it is also possible for just the two memory units 100, 200 to be connected to one another.

Furthermore, provision is made of a first connection region 102 with first connection units 101, via which the non-volatile memory unit 200 can be connected to external circuit units (not shown).

A second connection region 202 has second connection units 201, via which the volatile memory unit 100 can be connected to external circuit units (not shown). An essential advantage of the circuit arrangement according to the invention is that the volatile memory unit 100 and the non-volatile memory unit 200 are accommodated in a common housing 303, an item of repair information with regard to the volatile memory unit 100 being able to be permanently stored in the non-volatile memory unit 200.

It should be pointed out that more than one volatile memory unit 100 and/or more than one non-volatile memory unit 200 may be arranged in the housing 303, even though this is not illustrated in the figures.

In the fabrication of the electronic circuit arrangement in accordance with FIG. 1, the advantage is afforded that at least in each case one volatile memory (volatile memory unit 100) is fixedly and unambiguously connected or assigned to a non-volatile memory (non-volatile memory unit 200), so that the non-volatile memory unit 200 may potentially also be utilized for storing information which is accessed by the volatile memory unit 100.

In the context of fabricating multi-chip products of this type, a final electrical functional test is unavoidable. A yield in the case of such a last test step is critical since firstly the failure probabilities of the individual modules contained in the multi-chip package (the multichip housing) multiply, and secondly the value of a multi-chip product is significantly higher than that of the respective individual modules (that is to say of the volatile memory unit 100 and of the non-volatile memory unit 200). The arrangement according to the invention thus advantageously overcomes the disadvantage of the prior art, that is to say that it is possible to repair defective individual modules (volatile memory units 100) after incorporation into the housing 303.

According to the invention, items of information about addresses which have been identified as defective in a final functional test of the volatile memory unit are stored in the non-volatile memory unit 200 situated in the same housing 303.

In the housing 303, the connecting device 300 is typically formed by bonding wires that lead to the corresponding bonding pads. After a switch-on (start-up, power-up), the addressing logic of the volatile memory unit (DRAM) has to read the addresses of defective memory elements from the non-volatile memory unit 200 before the first reading or writing access to the volatile memory unit is effected.

Average persons skilled in the art know how an internal realization of the redundancy addresses has to be implemented, so that an explanation of this is omitted below. The repair information is provided via, for example, a serial connection 300 between the volatile memory unit 100 and the non-volatile memory unit 200.

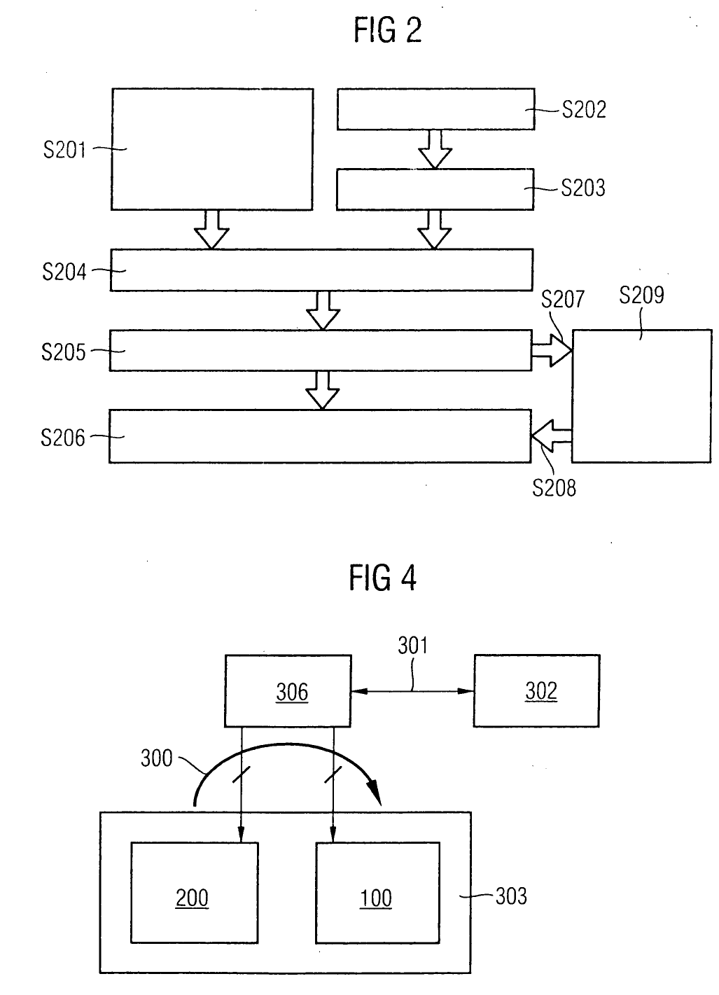

FIG. 2 shows a schematic flow diagram illustrating the essential steps of a test flow in the course of testing an electronic circuit arrangement on the basis of a multi-chip product. This shows the test flow which, by virtue of the method according to the invention, enables the possibility of a repair after a last functional test, that is to say after the volatile memory unit 100 and the non-volatile memory unit 200 have been incorporated into a common housing 303.

A test of the non-volatile memory unit 200 at the wafer level is carried out in a step S201. At the same time, it is possible to carry out a test of the volatile memory unit (e.g. the DRAM) at the wafer level in a step S202. If the volatile memory unit 100 has defects, then a subsequent step S203 typically involves effecting a conventional repair of the volatile memory unit 100 by means of, for example, conventional laser fuses. Finally, the volatile memory unit 100 and the non-volatile memory unit 200 are combined in order to be arranged in a single housing 303 (see FIG. 1) (step S204).

The electronic circuit arrangement arranged in the form of a multi-chip package (multichip housing) is then subjected to a functional test in a step S205. A functional test of this type is carried out both with regard to the non-volatile memory unit 200 and the volatile memory unit 100. A step S207 serves for recording an item of information about defective addresses, a repair solution being calculated in a step S209. In a step S208, repaired addresses of this type are returned to the electronic circuit arrangement, the repair information being stored in the non-volatile memory unit 200 (step S206).

Consequently, the method according to the invention makes it possible to provide a repair after the last functional test of the entire electronic circuit arrangement. This affords the advantage, in particular that a possibility of repairing a volatile memory unit provided as a volatile memory can be made possible after packaging into a housing 303, whereby the advantage of an improved yield is furthermore provided. Consequently, this furthermore expediently results in a reduced technological and circuitry outlay in the volatile memory, since defects that possibly occur can be eliminated by means of the information stored in the non-volatile memory unit 200. Consequently, the circuit arrangement according to the invention has the advantage that it has lower fabrication costs in comparison with a circuit arrangement manufactured in accordance with the prior art.

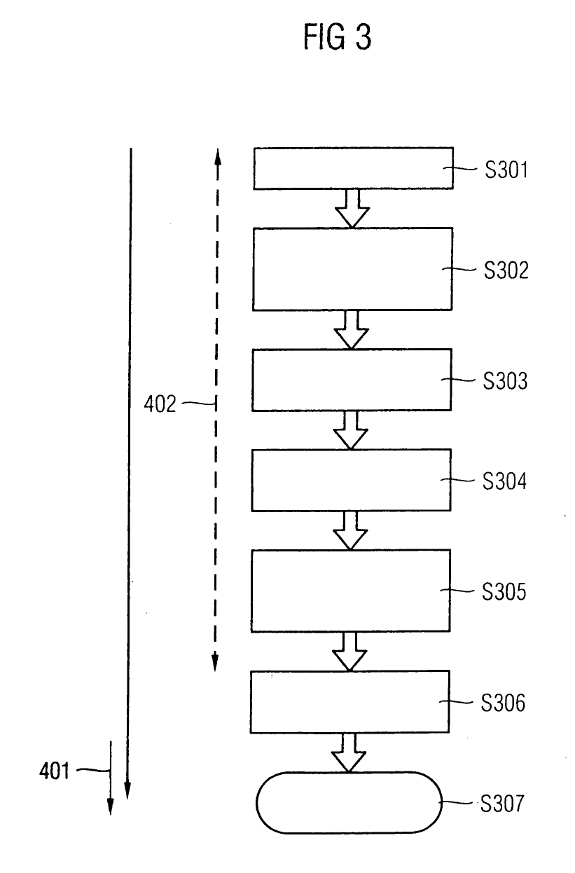

FIG. 3 shows a flow diagram for illustrating a schematic sequence of a transfer of the information stored in the non-volatile memory unit 200 to the volatile memory unit 100. In this case, an arrow bearing the reference symbol 401 designates the lapse of time, the time period indicated by the dashed double arrow representing the initialization time period.

In a step S301, an external supply voltage is supplied to the electronic circuit arrangement comprising the non-volatile memory unit 200 and the volatile memory unit 100. In a subsequent step S302, the voltage networks of the two circuit parts, that is to say of the non-volatile memory unit 200 and of the volatile memory unit 100, stabilize at their nominal voltages. In this way, the logic/state machine is ready and a chip ready signal is set. A subsequent step S303 provides for the volatile memory unit 100 to request an item of repair information via the connecting device 300 illustrated in FIG. 1.

Finally, the non-volatile memory unit 200 transfers the repair information to the volatile memory unit 100 in an arbitrary protocol (step S304). In the subsequent step S305, the volatile memory unit 100 (DRAM) decodes the protocol and reads the repair information, that is to say the addresses with defective memory elements. A redundancy circuit is initialized with the repair information. The initialization time period 402 has thus elapsed and encompasses a time from the beginning of step S301 described above to the end of step S305. In the subsequent step S306, the multi-chip package is provided for write and read operation steps and a first user access is possible. Step S307 which is illustrated in FIG. 3 represents subsequent operation steps relating to the operation of the entire electronic circuit arrangement. These are not essential to the invention and are therefore not explained in any further detail below.

It should be pointed out, although this is not illustrated in the drawings, that the non-volatile memory unit 200 requires an internal logic for the execution of step S304 above, which logic:

(i) “listens” to an external interrogation;

(ii) generates the internal addresses in order to access the memory area comprising the repair information;

(iii) converts the information into the suitable protocol; and

(iv) controls the OCD for the transfer.

It should be pointed out that it is not permitted to undershoot an initialization time period 402 prior to a start-up of the entire electronic circuit arrangement for a specific application.

FIG. 4 illustrates a further embodiment of a connecting device 300 according to the present invention. In the case illustrated in FIG. 4, an item of repair information is not transferred directly between the non-volatile memory unit 200 and the volatile memory unit 100, but rather via an external memory controller 306. In this case, the memory controller 306 or the microcontroller on which the latter is based has to control a corresponding transfer by means of a software. In particular, the advantage of this second embodiment is that, unlike in the first embodiment of the present invention, no particular requirements have to be made of the non-volatile memory unit 200.

A disadvantage of the second embodiment of the present invention which is illustrated in FIG. 4, on the other hand, is that it is necessary to provide adaptations to the controller 306 or the software for said memory controller 306 separately from the manufacture of multi-chip package, which makes an implementation more difficult overall and, from the point of view of the user, has the effect that adaptations to a firmware are necessary in the event of a change in manufacturer.

The memory controller 306 shown in FIG. 4 is driven by a processing device 302 via an interface unit 301.

It should be pointed out that the connecting device 300—shown in FIG. 1—for connecting the volatile memory unit 100 to the non-volatile memory unit 200 (NVM) may not only be provided as an electrical connection by means of conductor tracks, but may also be provided as a wire-free connection. A wire-free connecting device 300 of this type preferably comprises a radio connection of the volatile memory unit 100 to the non-volatile memory unit 200 (NVM), radiofrequency transceivers being provided.

It is furthermore possible to provide the connecting device as an optical connecting device for connecting the volatile memory unit 100 to the non-volatile memory unit 200, optical transceivers being provided both on the volatile memory unit 100 and on the non-volatile memory unit 200.

Depending on the application, it may be advantageous to combine a non-volatile memory unit 200 with more than one volatile memory unit 100 in a single circuit chip 303 or in a single electronic module, the non-volatile memory unit 200 then storing items of repair information on the at least two volatile memory units 100.

Although modifications and changes may be suggested by those skilled in the art, it is the intention of the inventors to embody within the patent warranted heron all changes and modifications as reasonably and properly come within the scope of their contribution to the art.

We claim as our invention:

1. An electronic circuit comprising:
a volatile memory unit and
a non-volatile memory, which stores a repair information related to said volatile memory unit and is connected to said volatile memory unit by a connecting device; said volatile and said non-volatile units being formed as a single electronic module.

2. The device of claim 1, wherein said volatile memory unit is a dynamic random access memory.

3. The device of claim 1, wherein said connecting device provides an electrical connection of said volatile memory unit to said non-volatile memory unit by means of conductor tracks.

4. The device of claim 1, wherein said connecting device provides a radio connection of said volatile memory unit to said non-volatile memory unit by means of radiofrequency transceivers.

5. The device of claim 1, wherein said connecting device provides an optical connection of said volatile memory unit to said non-volatile memory unit by means of optical transceivers.

6. The device of claim 1, wherein said non-volatile memory unit is combined with at least two of said volatile memory units in a single circuit chip.
